(19) United States
(12) Patent Application Publication
(10) Pub. No.: US 2013/0133731 A1
(43) Pub. Date: May 30, 2013

(54) CADMIUM DOPED TIN OXIDE BUFFER LAYER FOR THIN FILM PHOTOVOLTAIC DEVICES AND THEIR METHODS OF MANUFACTURE

(71) Applicants: Scott Daniel Feldman-Peabody, Golden, CO (US); Robert Dwayne Gossman, Aurora, CO (US); George Theodore Dalakos, Niskayuna, NY (US); Anping Zhang, Rexford, NY (US); Allan Robert Northrup, Schenectady, NY (US); Hong Piao, Rexford, NY (US); Laurie Le Tarte, Schenectady, NY (US)

(72) Inventors: Scott Daniel Feldman-Peabody, Golden, CO (US); Robert Dwayne Gossman, Aurora, CO (US); George Theodore Dalakos, Niskayuna, NY (US); Anping Zhang, Rexford, NY (US); Allan Robert Northrup, Schenectady, NY (US); Hong Piao, Rexford, NY (US); Laurie Le Tarte, Schenectady, NY (US)

(73) Assignee: PRIMESTAR SOLAR, INC., Arvada, CO (US)

(21) Appl. No.: 13/305,909

(22) Filed: Nov. 29, 2011

(51) Int. Cl. H01L 31/0216; H01B 1/08; H01L 31/18

(52) U.S. Cl. 136/256; 438/94; 252/512; 257/E31.119

(57) ABSTRACT

Methods for forming a resistive transparent buffer layer on a substrate are provided. The method can include depositing a resistive transparent buffer layer on a transparent conductive oxide layer on a substrate. The resistive transparent buffer layer can comprise a cadmium doped tin oxide that has an as-deposited stoichiometry where cadmium is present in an atomic amount that is less than 33% of a total atomic amount of tin and cadmium. Zinc may also be provided in the resistive transparent buffer layer in certain embodiments. Additionally, thin film photovoltaic devices having such resistive transparent buffer layers are provided.

### FIELD OF THE INVENTION

The subject matter disclosed herein relates generally to forming a resistive transparent buffer thin film layer. More particularly, the subject matter disclosed herein relates to methods of forming a resistive transparent buffer film layer for use in cadmium telluride thin film photovoltaic devices.

### BACKGROUND OF THE INVENTION

Thin film photovoltaic (PV) modules (also referred to as “solar panels”) based on cadmium telluride (CdTe) paired with cadmium sulfide (CdS) as the photo-reactive components are gaining wide acceptance and interest in the industry. CdTe is a semiconductor material having characteristics particularly suited for conversion of solar energy to electricity. For example, CdTe has an energy bandgap of about 1.45 eV, which enables it to convert more energy from the solar spectrum as compared to lower bandgap semiconductor materials historically used in solar cell applications (e.g., about 1.1 eV for silicon). Also, CdTe converts radiation energy in lower or diffuse light conditions as compared to the lower bandgap materials and, thus, has a longer effective conversion time over the course of a day or in cloudy conditions as compared to other conventional materials. The junction of the n-type layer and the p-type layer is generally responsible for the generation of electric potential and electric current when the CdTe PV module is exposed to light energy, such as sunlight. Specifically, the cadmium telluride (CdTe) layer and the cadmium sulfide (CdS) form a p-n heterojunction, where the CdTe layer acts as a p-type absorber layer (i.e., an electron accepting layer) and the CdS layer acts as a n-type window layer (i.e., an electron donating layer).

A transparent conductive oxide (“TCO”) layer is commonly used between the window glass and the junction forming layers. A resistive transparent buffer (“RTB”) layer can be present between the TCO layer and the n-type window layer to allow for a relatively thin n-type window layer to be formed to help minimize shunts and other deficiencies between the absorber layer and the TCO layer. However, atoms from the n-type window layer (e.g., Cd from a CdS layer) and/or atoms from the TCO layer (e.g., Cd from a cadmium tin oxide layer) can migrate into the RTB layer. This influx of atoms into the RTB layer can change its stoichiometry and may alter its functioning properties and characteristics in the device, especially over time. In some cases, the electrical and/or optical properties of the RTB can be improved. Additionally, the influx of atoms from the TCO layer may alter its conductive properties, especially in the case of cadmium atoms migrating from a cadmium tin oxide (CTO) layer into a RTB layer.

Thus, a need exists for a RTB layer having controlled stoichiometry in order to produce a more optimized and stabilized PV thin film device.

### BRIEF DESCRIPTION OF THE INVENTION

Aspects and advantages of the invention will be set forth in part in the following description, or may be obvious from the description, or may be learned through practice of the invention.

Methods are generally provided for forming a resistive transparent buffer layer on a substrate. In one embodiment, the method can include depositing a resistive transparent buffer layer on a transparent conductive oxide layer on a substrate. The resistive transparent buffer layer can comprise a cadmium doped tin oxide that has an as-deposited stoichiometry where cadmium is present in an atomic amount that is less than 33% of a total atomic amount of tin and cadmium.

For example, depositing the resistive transparent buffer layer can be achieved via sputtering a mixed target in a sputtering atmosphere such that the resistive transparent buffer layer is deposited on the substrate. The mixed target can include tin and cadmium (and optionally zinc), where the cadmium (and optional zinc) is present in an atomic amount that is less than 33% of a total atomic amount of tin and cadmium (and optional zinc). In one embodiment, the target can be a metal target sputtered in a sputtering atmosphere comprising oxygen. In an alternative embodiment, the target can be a ceramic target comprising tin, cadmium, and oxygen (and optionally zinc), where the sputtering target includes oxygen in a total amount that is within about +/−10% of an atomic amount of oxygen required to form a 1:2 atomic ratio of tin to oxygen and a 1:1 atomic ratio of oxygen to cadmium.

A resistive transparent buffer layer is also generally provided that can include tin, oxygen, and cadmium (and optionally zinc) in relative amounts such that cadmium (and any optional zinc) is present in an atomic amount that is less than 33% of a total atomic amount of tin and cadmium (and any optional zinc). Such a resistive transparent buffer thin film layer may be, for example, included in thin film photovoltaic devices. In one embodiment, the device can include a transparent conductive oxide layer on a transparent substrate. The transparent conductive oxide layer can comprise cadmium (e.g., a cadmium tin oxide). The resistive transparent buffer layer can be on the transparent conductive oxide layer. An n-type window layer can be on the resistive transparent buffer layer, and an absorber layer can be on the n-type window layer. A back contact layer can be on the absorber layer. In one embodiment, for instance, the resistive transparent buffer layer can include oxygen in a total amount that is within about +/−10% of an atomic amount of oxygen required to form a 1:2 atomic ratio of tin to oxygen and a 1:1 atomic ratio of oxygen to cadmium (and optional zinc).

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended figures, in which:

FIG. 1 shows a general schematic of a cross-sectional view of an exemplary cadmium telluride thin film photovoltaic device according to one embodiment of the present invention; and,

FIG. 2 shows a general schematic of a cross-sectional view of an exemplary DC sputtering chamber according to one embodiment of the present invention.

Repeat use of reference characters in the present specification and drawings is intended to represent the same or analogous features or elements.

### DETAILED DESCRIPTION OF THE INVENTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

In the present disclosure, when a layer is being described as “on” or “over” another layer or substrate, it is to be understood that the layers can either be directly contacting each other or have another layer or feature between the layers, unless otherwise stated. Thus, these terms are simply describing the relative position of the layers to each other and do not necessarily mean “on top of” since the relative position above or below depends upon the orientation of the device to the viewer. Additionally, although the invention is not limited to any particular film thickness, the term “thin” describing any film layers of the photovoltaic device generally refers to the film layer having a thickness less than about 10 micrometers (“microns” or “μm”).

It is to be understood that the ranges and limits mentioned herein include all ranges located within the prescribed limits (i.e., subranges). For instance, a range from about 100 to about 200 also includes ranges from 110 to 150, 170 to 190, 153 to 162, and 145.3 to 149.6. Further, a limit of up to about 7 also includes a limit of up to about 5, up to 3, and up to about 4.5, as well as ranges within the limit, such as from about 1 to about 5, and from about 3.2 to about 6.5.

Methods are generally disclosed for forming a resistive transparent buffer (“RTB”) layer on a substrate, along with the resulting PV devices formed. For example, the RTB layer can be deposited on a transparent conductive oxide layer on the substrate. The RTB layer can generally be deposited to include a cadmium doped tin oxide. In one embodiment, the RTB layer can further include zinc. The presence of cadmium in the RTB layer as deposited may inhibit or prevent diffusion of cadmium from a TCO layer (e.g., a TCO layer that includes a cadmium) and/or a n-type window layer (e.g., a n-type window layer that includes CdS). Thus, the inclusion of cadmium in the RTB layer may help stabilize the resulting thin film stack in the PV device. For example, keeping cadmium within a TCO layer can help prevent reducing the conductivity of the TCO layer, which can lead to improved PV device efficiency.

The RTB layer can, in one embodiment, be a cadmium doped tin oxide that has an as-deposited stoichiometry where cadmium is present in an atomic amount that is less than 33% of a total atomic amount of tin and cadmium. This atomic percent can be calculated by the number of cadmium atoms (Cd) divided by the sum of the number of cadmium atoms and tin atoms (Cd+Sn) times 100: Cd/(Cd+Sn)*100. In certain embodiments, the cadmium doped tin oxide can have an as-deposited stoichiometry where cadmium is present in an atomic amount that is about 0.5 atomic % to about 25 atomic % of a total atomic amount of tin and cadmium (e.g., about 1% to about 10% of a total amount of tin and cadmium).

In certain embodiments, cadmium can be present in the RTB layer in an atomic amount up to 7.5 atomic %, such as about 0.1 atomic % to about 5 atomic %. In one embodiment, for instance, cadmium can be present in the RTB layer in an atomic amount of about 0.1 atomic % to about 3 atomic %.

In one embodiment, the RTB layer can further include zinc. Thus, in certain embodiments, the RTB layer can include a cadmium and zinc doped tin oxide. When zinc is present, the as-deposited stoichiometry can be where cadmium and tin are present in an atomic amount that is less than 33% of a total atomic amount of tin, zinc, and cadmium. This atomic percent can be calculated by the sum of cadmium atoms and zinc atoms (Cd+Zn) divided by the sum of the number of cadmium atoms, zinc atoms, and tin atoms (Cd+Zn+Sn) times 100: (Cd+Zn)/(Cd+Zn+Sn)*100. In certain embodiments, the cadmium and zinc doped tin oxide can have an as-deposited stoichiometry where cadmium and tin are present in an atomic amount that is about 0.5 atomic % to about 25 atomic % of a total atomic amount of tin, zinc, and cadmium (e.g., about 1% to about 10% of a total amount of tin, zinc, and cadmium).

In certain embodiments, zinc can be present in the RTB layer in an atomic amount up to 7.5 atomic %, such as about 0.1 atomic % to about 5 atomic %. In one embodiment, for instance, zinc can be present in the RTB layer in an atomic amount of about 0.1 atomic % to about 3 atomic %.

Due to the relatively low amount of cadmium present in the RTB layer, cadmium stannate and other common variations of cadmium tin oxide are not prominently formed in the RTB layer. For example, the stoichiometry of the cadmium doped tin oxide can be less than required for forming a cadmium stannate layer or a variation thereof. As is known in the art, cadmium stannate has a stoichiometry according to the formula: Cd₂SnO₄. Other common phases of a cadmium tin oxide include CdSn₂O₅ and/or CdSnO₃. However, as stated, cadmium stannate and these other common variations of cadmium tin oxide are not prominently formed in the RTB layer. As such, cadmium is present in these cadmium tin oxides in an atomic amount that is 33% or more of the total atomic amount of tin and cadmium.

In one embodiment, the RTB layer can be deposited via a sputtering deposition process. Such a sputtering process can include sputtering a mixed target (e.g., containing cadmium, tin, and optionally zinc) or via co-sputtering a plurality of targets. For example, the RTB layer can be deposited via sputtering a mixed target that includes cadmium and tin and, optionally, zinc. The sputtering target can, in one embodiment, include tin and cadmium, the cadmium being present in the same atomic percent as discussed above with respect to the as-deposited stoichiometry of the cadmium doped tin oxide of the RTB layer (e.g., in an atomic amount that is less than 33% of a total atomic amount of tin and cadmium). Such a sputtering target can be constructed of a mixed metal material or a ceramic material.

When constructed from a mixed metal material, the mixed metal target can include tin and cadmium (and optionally zinc). In this embodiment, the sputtering atmosphere can include oxygen to form the cadmium (and optionally zinc) doped tin oxide layer through reactive sputtering. For example, the mixed metal target can include tin and cadmium such that cadmium is included in an atomic amount that is less than 33% of a total atomic amount of tin and cadmium. Additionally, the mixed metal target can further include zinc such that cadmium and zinc are included in an atomic amount that is less than 33% of a total atomic amount of tin, zinc, and cadmium. For example, zinc can be included in an amount of about 0.1 atomic % to about 3 atomic % of the total atomic amount of tin, zinc, and cadmium. Such a mixed metal target can be substantially free from oxygen.

When constructed from a ceramic material, the ceramic target can include tin, cadmium, and oxygen (and optionally zinc) in relative amounts that form a tin oxide doped with cadmium upon sputtering. For example, the ceramic target can include tin, oxygen, and cadmium in relative amounts such that cadmium is present in an atomic amount that is less than 33% of a total atomic amount of tin and cadmium. Additionally, the sputtering target can include oxygen in an amount sufficient to form oxides with the metals (e.g., SnO₂, CdO, and ZnO). As such, oxygen can be present in a total amount that is within about +/−10% (e.g., within about +/−5%) of the atomic amount of oxygen required to form a 1:2 atomic ratio of tin to oxygen and a 1:1 atomic ratio of oxygen to cadmium and zinc. In one particular embodiment, oxygen can be present in the sputtering target in a total amount that is within about +/−1% of the atomic amount of oxygen required to form a 1:2 atomic ratio of tin to oxygen and a 1:1 atomic ratio of oxygen to cadmium and zinc. It is noted that the total amount of oxygen in such a ceramic target is the sum of the oxygen atomic ratios described herein (i.e., the sum of oxygen from the tin to oxygen ratio and the oxygen to cadmium, zinc ratio). Such a ceramic target can be sputtered in an inert atmosphere (e.g., including an inert gas, such as argon and/or can be substantially free from oxygen) or, alternatively, in an atmosphere comprising oxygen.

In one particular embodiment, for example, the ceramic sputtering target can include tin oxide and cadmium oxide (and optionally zinc oxide) in relative amounts such that cadmium is included in an atomic amount that is less than 33% of a total atomic amount of tin and cadmium. The ceramic sputtering target can be, in one embodiment, substantially free of cadmium stannate and/or any common variation of cadmium tin oxide (e.g., CdSn₂O₅ and/or CdSnO₃), so as to form a RTB layer that is substantially free of cadmium stannate and/or common variations of cadmium tin oxide. Such a ceramic sputtering target can be formed by pressing tin oxide and cadmium oxide (and optionally zinc oxide) together utilizing suitable heat and pressure.

Accordingly, in one embodiment, the RTB layer formed (via any method) can include oxygen in an amount sufficient to form oxides with the metals (e.g., SnO₂, CdO, and ZnO). As such, oxygen can be present in the RTB layer in a total amount that is within about +/−10% (e.g., within about +/−5%) of the atomic amount of oxygen required to form a 1:2 atomic ratio of tin to oxygen and a 1:1 atomic ratio of oxygen to cadmium and zinc. In one particular embodiment, oxygen can be present in the RTB layer in a total amount that is within about +/−1% of the atomic amount of oxygen required to form a 1:2 atomic ratio of tin to oxygen and a 1:1 atomic ratio of oxygen to cadmium and zinc. It is noted that the total amount of oxygen in such a RTB layer is the sum of the oxygen atomic ratios described herein (i.e., the sum of oxygen from the tin to oxygen ratio and the oxygen to cadmium, zinc ratio). Such an amount of oxygen can help ensure that tin oxide (SnO₂), cadmium oxide (CdO), and zinc oxide (ZnO) are primarily formed in the RTB layer. For example, in one particular embodiment, the RTB layer may be substantially free from cadmium stannate (i.e., Cd₂SnO₄) and/or other common variations of cadmium tin oxide (CdSn₂O₅ and/or CdSnO₃). As used herein, the term “substantially free” means no more than an insignificant trace amount present and encompasses completely free (e.g., 0 molar % up to 0.01 molar %).

Sputtering deposition generally involves ejecting material from a target, which is the material source, and depositing the ejected material onto the substrate to form the film. DC sputtering generally involves applying a direct current to a metal target (i.e., the cathode) positioned near the substrate (i.e., the anode) within a sputtering chamber to form a direct-current discharge. The sputtering chamber can have a reactive atmosphere (e.g., an oxygen atmosphere, nitrogen atmosphere, fluorine atmosphere) that forms a plasma field between the metal target and the substrate. Other inert gases (e.g., argon, etc.) may also be present. The pressure of the reactive atmosphere can be between about 1 mTorr and about 20 mTorr for magnetron sputtering. The pressure can be even higher for diode sputtering (e.g., from about 25 mTorr to about 100 mTorr). When metal atoms are released from the target upon application of the voltage, the metal atoms deposit onto the surface of the substrate. For example, when the atmosphere contains oxygen, the metal atoms released from the metal target can form a metallic oxide layer on the substrate. The current applied to the source material can vary depending on the size of the source material, size of the sputtering chamber, amount of surface area of substrate, and other variables. In some embodiments, the current applied can be from about 2 amps to about 20 amps.

Conversely, RF sputtering involves exciting a capacitive discharge by applying an alternating-current (AC) or radio-frequency (RF) signal between the target (e.g., a ceramic source material) and the substrate. The sputtering chamber can have an inert atmosphere (e.g., an argon atmosphere) which may or may not contain reactive species (e.g., oxygen, nitrogen, etc.) having a pressure between about 1 mTorr and about 20 mTorr for magnetron sputtering. Again, the pressure can be even higher for diode sputtering (e.g., from about 25 mTorr to about 100 mTorr).

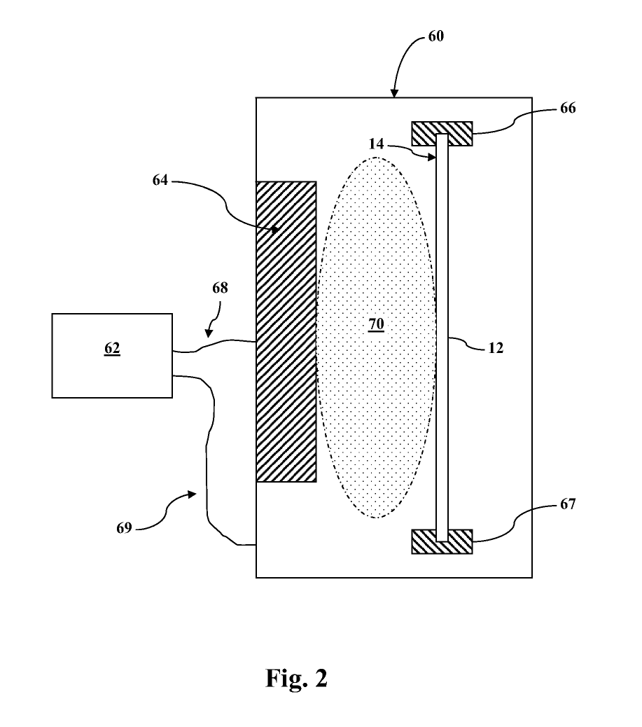

FIG. 2 shows a general schematic as a cross-sectional view of an exemplary DC sputtering chamber 60 according to one embodiment of the present invention. A DC power source 62 is configured to control and supply DC power to the chamber 60. As shown, the DC power source applies a voltage to the cathode 64 to create a voltage potential between the cathode 64 and an anode formed by the chamber wall, such that the substrate is in between the cathode and anode. The glass substrate 12 is held between top support 66 and bottom support 67 via wires 68 and 69, respectively. Generally, the glass substrate is positioned within the sputtering chamber 60 such that the RTB layer is formed over the TCO layer 14 on the substrate 12 that faces the cathode 64.

A plasma field 70 is created once the sputtering atmosphere is ignited, and is sustained in response to the voltage potential between the cathode 64 and the chamber wall acting as an anode. The voltage potential causes the plasma ions within the plasma field 70 to accelerate toward the cathode 64, causing atoms from the cathode 64 to be ejected toward the surface on the glass substrate 12. As such, the cathode 64 can be referred to as a “target” and acts as the source material for the formation of the RTB layer on the TCO layer 14 on the substrate 12 that faces the cathode 64. As stated, the cathode 64 can be a mixed metal target, such as elemental tin, cadmium, and/or zinc, or mixtures thereof. Additionally, in some embodiments, a plurality of cathodes 64 can be utilized. A plurality of cathodes 64 can be particularly useful to form a layer including several types of materials (e.g., co-sputtering). Since the sputtering atmosphere can contain oxygen gas, particularly when utilizing a metal target, oxygen particles of the plasma field 70 can react with the ejected target atoms to form a RTB layer on the TCO layer 14 on the substrate 12.

Although only a single DC power source 62 is shown, the voltage potential can be realized through the use of multiple power sources coupled together. Additionally, the exemplary sputtering chamber 60 is shown having a vertical orientation, although any other configuration can be utilized.

For example, the RTB layer can be formed via sputtering at the specified sputtering temperature from a mixed target 64 to form the RTB layer discussed above on the TCO layer 14 on the substrate 12.

The presently provided methods of sputtering a RTB layer can be utilized in the formation of any film stack that utilizes a RTB layer, particularly those including a TCO layer formed from cadmium stannate and/or an n-type window layer formed from cadmium sulfide. For example, the RTB layer can be used during the formation of any cadmium telluride device that utilizes a cadmium telluride layer, such as in the cadmium telluride thin film photovoltaic device disclosed in U.S. Publication No. 2009/0194165 of Murphy, et al. titled “Ultra-high Current Density Cadmium Telluride Photovoltaic Modules.”

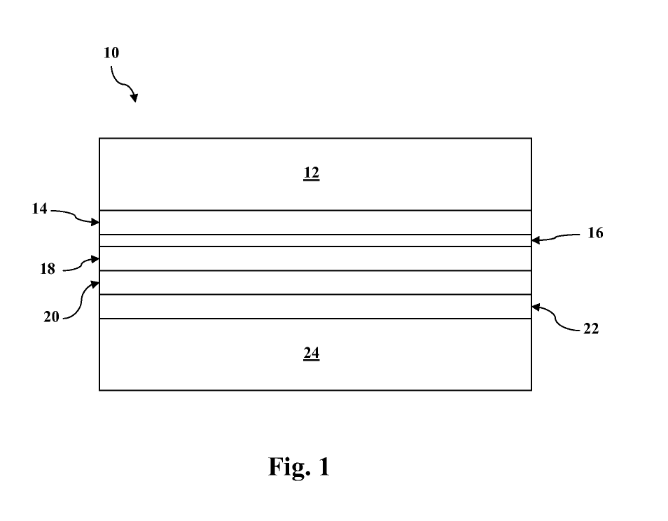

FIG. 1 represents an exemplary cadmium telluride thin film photovoltaic device 10 that can be formed according to methods described herein. The exemplary device 10 of FIG. 1 includes a top sheet of glass 12 employed as the substrate. In this embodiment, the glass 12 can be referred to as a “superstrate,” as it is the substrate on which the subsequent layers are formed even though it faces upward to the radiation source (e.g., the sun) when the cadmium telluride thin film photovoltaic device 10 is in use. The top sheet of glass 12 can be a high-transmission glass (e.g., high transmission borosilicate glass), low-iron float glass, or other highly transparent glass material. The glass is generally thick enough to provide support for the subsequent film layers (e.g., from about 0.5 mm to about 10 mm thick), and is substantially flat to provide a good surface for forming the subsequent film layers. In one embodiment, the glass 12 can be a low iron float glass containing less than about 0.015% by weight iron (Fe), and may have a transmissivity of about 0.9 or greater in the spectrum of interest (e.g., wavelengths from about 300 nm to about 900 nm). In another embodiment, borosilicate glass may be utilized so as to better withstand high temperature processing. For example, a borosilicate glass can have a thickness of about 0.5 mm to about 2.5 mm.

The transparent conductive oxide (TCO) layer 14 is shown on the glass 12 of the exemplary device 10 of FIG. 1. The TCO layer 14 allows light to pass through with minimal absorption while also allowing electric current produced by the device 10 to travel sideways to opaque metal conductors (not shown). For instance, the TCO layer 14 can have a sheet resistance less than about 30 ohm per square, such as from about 4 ohm per square to about 20 ohm per square (e.g., from about 8 ohm per square to about 15 ohm per square). In certain embodiments, the TCO layer 14 can have a thickness between about 0.1 μm and about 1 μm, for example from about 0.1 μm to about 0.5 μm, such as from about 0.25 μm to about 0.35 μm.

The resistive transparent buffer layer 16 (RTB layer) is shown on the TCO layer 14 on the exemplary cadmium telluride thin film photovoltaic device 10. The RTB layer 16 is generally more resistive than the TCO layer 14 and can help protect the device 10 from chemical interactions between the TCO layer 14 and the subsequent layers during processing of the device 10. For example, in certain embodiments, the RTB layer 16 can have a sheet resistance that is greater than about 1000 ohms per square, such as from about 10 kOhms per square to about 1000 MOhms per square. The RTB layer 16 can also have a wide optical bandgap (e.g., greater than about 2.5 eV, such as from about 2.7 eV to about 3.0 eV).

Without wishing to be bound by a particular theory, it is believed that the presence of the RTB layer 16 between the TCO layer 14 and the cadmium sulfide layer 18 can allow for a relatively thin cadmium sulfide layer 18 to be included in the device 10 by reducing the possibility of interface defects (i.e., “pinholes” in the cadmium sulfide layer 18) creating shunts between the TCO layer 14 and the cadmium telluride layer 22. Thus, it is believed that the RTB layer 16 allows for improved adhesion and/or interaction between the TCO layer 14 and the cadmium telluride layer 22, thereby allowing a relatively thin cadmium sulfide layer 18 to be formed thereon without significant adverse effects that would otherwise result from such a relatively thin cadmium sulfide layer 18 formed directly on the TCO layer 14.

The RTB layer 16 is described in greater detail above, and can include, for instance, a cadmium doped tin oxide (SnO₂) and optionally zinc oxide, which can be referred to as a cadmium doped zinc tin oxide layer (“Cd:ZTO”). In one particular embodiment, the RTB layer 16 can include more tin oxide than zinc oxide. For example, the RTB layer 16 can have a composition with a stoichiometric ratio of ZnO/SnO₂ between about 0.25 and about 3, such as in about an one to two (1:2) stoichiometric ratio of tin oxide to zinc oxide. As stated, the RTB layer 16 can be formed by sputtering, chemical vapor deposition, spraying pyrolysis, or any other suitable deposition method. In one particular embodiment, the RTB layer 16 can be formed by sputtering (e.g. DC sputtering or RF sputtering) on the TCO layer 14 (as discussed below in greater detail above).

In certain embodiments, the RTB layer 16 can have a thickness between about 0.075 μm and about 1 μm, for example from about 0.1 μm to about 0.5 μm. In particular embodiments, the RTB layer 16 can have a thickness between about 0.08 μm and about 0.2 μm, for example from about 0.1 μm to about 0.15 μm.

An n-type window layer 18 is shown on RTB layer 16 of the exemplary device 10 of FIG. 1. In one embodiment, the n-type window layer 18 can generally include cadmium sulfide but may also include other materials, such as zinc sulfide, cadmium zinc sulfide, etc., and mixtures thereof as well as dopants and other impurities (i.e., forming a cadmium sulfide layer). In this embodiment, the cadmium sulfide layer may include oxygen up to about 25% by atomic percentage, for example from about 5% to about 20% by atomic percentage. Such a cadmium sulfide layer can have a wide band gap (e.g., from about 2.25 eV to about 2.5 eV, such as about 2.4 eV) in order to allow most radiation energy (e.g., solar radiation) to pass. As such, the cadmium sulfide layer 18 is considered a transparent layer on the device 10.

The cadmium sulfide layer 18 can be formed by sputtering, chemical vapor deposition, chemical bath deposition, and other suitable deposition methods. In one particular embodiment, the cadmium sulfide layer 18 can be formed by sputtering (e.g., direct current (DC) sputtering or radio frequency (RF) sputtering) on the resistive transparent layer 16.

Due to the presence of the resistive transparent layer 16, the n-type window layer 18 can have a thickness that is less than about 0.1 μm, such as between about 10 nm and about 100 nm, such as from about 50 nm to about 80 nm, with a minimal presence of pinholes between the resistive transparent layer 16 and the n-type window layer 18. Additionally, a n-type window layer 18 having a thickness less than about 0.1 μm reduces any absorption of radiation energy by the n-type window layer 18, effectively increasing the amount of radiation energy reaching the underlying absorption layer 22.

An absorption layer 20 is shown on the n-type window layer 18 in the exemplary thin film photovoltaic device 10 of FIG. 1. The absorber layer 20 is a p-type layer that interacts with the n-type window layer 18 (e.g., the cadmium sulfide layer) to produce current from the absorption of radiation energy by absorbing the majority of the radiation energy passing into the device 10 due to its high absorption coefficient and creating electron-hole pairs. In one particular embodiment, the absorber layer can include cadmium telluride (i.e., a cadmium telluride layer); however, other materials can include, but are not limited to, (Ag,Cu)(In,Ga)(Se,S)₂, (Ag,Cu)ZnSn(Se,S), GaAs, amorphous Si, or other absorber materials.

For example, when the absorber layer 20 is formed from cadmium telluride, the resulting cadmium telluride layer 20 can have a bandgap tailored to absorb radiation energy (e.g., from about 1.4 eV to about 1.5 eV, such as about 1.45 eV) to create the maximum number of electron-hole pairs with the highest electrical potential (voltage) upon absorption of the radiation energy. Electrons may travel from the p-type side (i.e., the cadmium telluride layer 20) across the junction to the n-type side (i.e., the cadmium sulfide layer 18) and, conversely, holes may pass from the n-type side to the p-type side. Thus, the p-n junction formed between the cadmium sulfide layer 18 and the cadmium telluride layer 20 forms a diode in which the charge imbalance leads to the creation of an electric field spanning the p-n junction. Conventional current is allowed to flow in only one direction and separates the light induced electron-hole pairs.

The absorber layer 20 can be formed by any known process, such as vapor transport deposition, chemical vapor deposition (CVD), spray pyrolysis, electro-deposition, sputtering, close-space sublimation (CSS), etc. In one particular embodiment, the n-type window layer 18 is deposited by a sputtering and the absorber layer 20 is deposited by close-space sublimation. In particular embodiments, the absorber layer 20 can have a thickness between about 0.1 μm and about 10 μm, such as from about 1 μm and about 5 μm. In one particular embodiment, the absorber layer 20 can have a thickness between about 2 μm and about 4 μm, such as about 3 μm.

A series of post-forming treatments can be applied to the exposed surface of the absorber layer 20. These treatments can tailor the functionality of the absorber layer 20 and prepare its surface for subsequent adhesion to the back contact layer(s) 22. For example, when formed from cadmium telluride, the absorber layer 20 can be annealed at elevated temperatures (e.g., from about 350° C. to about 500° C., such as from about 375° C. to about 424° C.) for a sufficient time (e.g., from about 1 to about 10 minutes) to create a quality p-type layer of cadmium telluride. Without wishing to be bound by theory, it is believed that annealing the cadmium telluride layer 20 (and the device 10) converts the normally lightly p-type doped, or even n-type doped cadmium telluride layer 20 to a more strongly p-type cadmium telluride layer 20 having a relatively low resistivity. Additionally, the cadmium telluride layer 20 can recrystallize and undergo grain growth during annealing.

Annealing the cadmium telluride layer 20 can be carried out in the presence of cadmium chloride in order to dope the cadmium telluride layer 20 with chloride ions. For example, the cadmium telluride layer 20 can be washed with an aqueous solution containing cadmium chloride and then annealed at the elevated temperature.

In one particular embodiment, after annealing the cadmium telluride layer 20 in the presence of cadmium chloride, the surface can be washed to remove any cadmium oxide formed on the surface. This surface preparation can leave a Te-rich surface on the cadmium telluride layer 20 by removing oxides from the surface, such as CdO, CdTeO₃, CdTe₂O₅, etc. For instance, the surface can be washed with a suitable solvent (e.g., ethylenediamine also known as 1,2 diaminoethane or “DAE”) to remove any cadmium oxide from the surface.

Additionally, copper can be added to the cadmium telluride layer 20. Along with a suitable etch, the addition of copper to the cadmium telluride layer 20 can form a surface of copper-telluride on the cadmium telluride layer 20 in order to obtain a low-resistance electrical contact between the cadmium telluride layer 20 (i.e., the p-type layer) and the back contact layer(s). Specifically, the addition of copper can create a surface layer of cuprous telluride (Cu₂Te) between the cadmium telluride layer 20 and the back contact layer 22. Thus, the Te-rich surface of the cadmium telluride layer 20 can enhance the collection of current created by the device through lower resistivity between the cadmium telluride layer 20 and the back contact layer 22.

Copper can be applied to the exposed surface of the cadmium telluride layer 20 by any process. For example, copper can be sprayed or washed on the surface of the cadmium telluride layer 20 in a solution with a suitable solvent (e.g., methanol, water, or the like, or combinations thereof) followed by annealing. In particular embodiments, the copper may be supplied in the solution in the form of copper chloride, copper iodide, or copper acetate. The annealing temperature is sufficient to allow diffusion of the copper ions into the cadmium telluride layer 20, such as from about 125° C. to about 300° C. (e.g. from about 150° C. to about 200° C.) for about 5 minutes to about 30 minutes, such as from about 10 to about 25 minutes.

A back contact layer 22 is shown on the cadmium telluride layer 20. The back contact layer 22 generally serves as the back electrical contact, in relation to the opposite, TCO layer 14 serving as the front electrical contact. The back contact layer 22 can be formed on, and in one embodiment is in direct contact with, the cadmium telluride layer 20. The back contact layer 22 is suitably made from one or more highly conductive materials, such as elemental nickel, chromium, copper, tin, aluminum, gold, silver, technetium or alloys or mixtures thereof. Additionally, the back contact layer 22 can be a single layer or can be a plurality of layers. In one particular embodiment, the back contact layer 22 can include graphite, such as a layer of carbon deposited on the p-layer followed by one or more layers of metal, such as the metals described above. The back contact layer 22, if made of or comprising one or more metals, is suitably applied by a technique such as sputtering or metal evaporation. If it is made from a graphite and polymer blend, or from a carbon paste, the blend or paste is applied to the semiconductor device by any suitable method for spreading the blend or paste, such as screen printing, spraying or by a “doctor” blade. After the application of the graphite blend or carbon paste, the device can be heated to convert the blend or paste into the conductive back contact layer. A carbon layer, if used, can be from about 0.1 μm to about 10 μm in thickness, for example from about 1 μm to about 5 μm. A metal layer of the back contact, if used for or as part of the back contact layer 22, can be from about 0.1 μm to about 1.5 μm in thickness.

The encapsulating glass 24 is also shown in the exemplary cadmium telluride thin film photovoltaic device 10 of FIG. 1.

Other components (not shown) can be included in the exemplary device 10, such as bus bars, external wiring, laser etches, etc. For example, when the device 10 forms a photovoltaic cell of a photovoltaic module, a plurality of photovoltaic cells can be connected in series in order to achieve a desired voltage, such as through an electrical wiring connection. Each end of the series connected cells can be attached to a suitable conductor such as a wire or bus bar, to direct the photovoltaically generated current to convenient locations for connection to a device or other system using the generated electric. A convenient means for achieving such series connections is to laser scribe the device to divide the device into a series of cells connected by interconnects. In one particular embodiment, for instance, a laser can be used to scribe the deposited layers of the semiconductor device to divide the device into a plurality of series connected cells.

Although not specifically shown in FIG. 1, other thin film layers may also be present in the thin film stack. For example, index matching layers can be positioned between the transparent conductive oxide layer 14 and the transparent substrate 12. Additionally, an oxygen getter layer (e.g., comprising alumina) can be positioned between the transparent conductive oxide layer 14 and the resistive transparent buffer layer 16.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. A method of forming a resistive transparent buffer layer on a substrate, the method comprising:
depositing a resistive transparent buffer layer on a transparent conductive oxide layer on a substrate, wherein the resistive transparent buffer layer comprises a cadmium doped tin oxide that has an as-deposited stoichiometry where cadmium is present in an atomic amount that is less than 33% of a total atomic amount of tin and cadmium.

2. The method as in claim 1, wherein the resistive transparent buffer layer includes oxygen in a total amount that is within about +/−10% of an atomic amount of oxygen required to form a 1:2 atomic ratio of tin to oxygen and a 1:1 atomic ratio of oxygen to cadmium.

3. The method as in claim 1, depositing the resistive transparent buffer layer comprises sputtering a mixed target in a sputtering atmosphere such that the resistive transparent buffer layer is deposited on the substrate, wherein the mixed target comprises tin and cadmium, the cadmium being present in an atomic amount that is less than 33% of a total atomic amount of tin and cadmium.

4. The method as in claim 3, wherein the target is a metal target, and wherein the sputtering atmosphere comprises oxygen.

5. The method as in claim 3, wherein the target is a ceramic target comprising tin, cadmium, and oxygen, wherein the sputtering target includes oxygen in a total amount that is within about +/−10% of an atomic amount of oxygen required to form a 1:2 atomic ratio of tin to oxygen and a 1:1 atomic ratio of oxygen to cadmium.

6. The method as in claim 1, wherein the resistive transparent buffer layer includes cadmium in an atomic amount that is about 0.5 atomic % to about 25 atomic % of a total atomic amount of tin and cadmium.

7. The method as in claim 1, wherein the resistive transparent buffer layer includes cadmium in an atomic amount that is about 1% to about 10% of a total atomic amount of tin and cadmium.

8. The method as in claim 1, wherein the resistive transparent buffer layer further comprises zinc.

9. The method as in claim 8, wherein zinc is present in the resistive transparent buffer layer in an amount of about 0.1 atomic % to about 3 atomic %.

10. The method as in claim 8, wherein the resistive transparent buffer layer includes cadmium and zinc in a combined atomic amount that is less than 33% of a total atomic amount of tin, zinc, and cadmium.

11. The method as in claim 8, wherein the resistive transparent buffer layer includes cadmium and zinc in a combined atomic amount that is about 1% to about 10% of a total atomic amount of tin, zinc, and cadmium.

12. The method as in claim 8, wherein the resistive transparent buffer layer includes oxygen in a total amount that is within about +/−10% of an atomic amount of oxygen required to form a 1:2 atomic ratio of tin to oxygen and a 1:1 atomic ratio of oxygen to cadmium and zinc.

13. The method as in claim 1, wherein the transparent conductive oxide layer comprises cadmium stannate, fluorine doped tin oxide, aluminum doped zinc oxide, indium tin oxide, or a mixture thereof.

14. The method as in claim 1, further comprising:
depositing a n-type window layer on the resistive transparent buffer layer, wherein the n-type window layer comprises cadmium sulfide;
depositing an absorber layer on the n-type window layer on the n-type window layer, wherein the absorber layer comprises cadmium telluride.

15. A resistive transparent buffer thin film layer comprising tin, oxygen, and cadmium, wherein the resistive transparent buffer layer includes cadmium in an atomic amount that is less than 33% of a total atomic amount of tin and cadmium.

16. The resistive transparent buffer thin film layer as in claim 15, wherein oxygen is included in a total amount that is within about +/−10% of an atomic amount of oxygen required to form a 1:2 atomic ratio of tin to oxygen and a 1:1 atomic ratio of oxygen to cadmium.

17. The resistive transparent buffer thin film layer as in claim 15, further comprising zinc.

18. The resistive transparent buffer thin film layer as in claim 17, wherein oxygen is included in a total amount that is within about +/−10% of an atomic amount of oxygen required to form a 1:2 atomic ratio of tin to oxygen and a 1:1 atomic ratio of oxygen to cadmium and zinc.

19. A thin film photovoltaic device, comprising:
a transparent substrate;
a transparent conductive oxide layer on the transparent substrate, wherein the transparent conductive oxide layer comprises cadmium;
a resistive transparent buffer layer on the transparent conductive oxide layer, wherein the resistive transparent buffer layer comprises tin, oxygen, and cadmium, wherein the resistive transparent buffer layer includes cadmium in an atomic amount that is less than 33% of a total atomic amount of tin and cadmium;
an n-type window layer on the resistive transparent buffer layer;
an absorber layer on the n-type window layer; and,
a back contact layer on the absorber layer.

20. The device of claim 19, wherein oxygen is included in a total amount that is within about +/−10% of an atomic amount of oxygen required to form a 1:2 atomic ratio of tin to oxygen and a 1:1 atomic ratio of oxygen to cadmium and zinc.
